(19) United States
(12) Patent Application Publication
(10) Pub. No.: US 2014/0332895 A1
(43) Pub. Date: Nov. 13, 2014

(54) RANDOM NUMBER GENERATION DEVICE

(71) Applicant: KABUSHIKI KAISHA TOSHIBA, Minato-ku (JP)

(72) Inventors: Shigeki KOBAYASHI, Kanagawa-ken (JP); Ken UCHIDA, Tokyo (JP); Shinobu FUJITA, Tokyo (JP); Tetsufumi TANAMOTO, Kanagawa-ken (JP)

(73) Assignee: KABUSHIKI KAISHA TOSHIBA, Minato-ku (JP)

(21) Appl. No.: 14/446,067

(22) Filed: Jul. 29, 2014

Related U.S. Application Data
(62) Division of application No. 12/391,640, filed on Feb. 24, 2009.

(30) Foreign Application Priority Data
Jun. 13, 2008 (JP) 2008-156027

(51) Int. Cl. H01L 29/10; H01L 27/088

(52) U.S. Cl. CPC H01L 29/1054; H01L 27/088
USPC 257/368

(57) ABSTRACT

A random number generation device includes: a first source region; a first drain region; a first channel region provided between the first source region and the first drain region; a first insulating film provided on the first channel region; and a first gate electrode provided on the first insulating film. The first insulating film has a trap capturing and releasing a charge, and a tensile or compressive stress is applied in a direction of a gate length to at least one of the first channel region and the first insulating film.

### CROSS-REFERENCE TO RELATED APPLICATIONS

This application is based upon and claims the benefit of priority from the prior Japanese Patent Application No. 2008-156027, filed on Jun. 13, 2008; the entire contents of which are incorporated herein by reference.

### BACKGROUND OF THE INVENTION

1. Field of the Invention

This invention relates to a random number generation device having a MISFET structure.

2. Background Art

In an information security field of a highly-networked information society, a compact device generating random numbers at high speed is desired. This is because the random number is used for production of a key of secret code or the like. For generating random numbers, pseudo-random numbers generated by software are usually used. However, for more improvement of the information security, utilizing true random numbers generated by random physical phenomena is absolutely necessary, and the importance of a random number generation device based on the true random number has extremely increased.

As a random number generation device utilizing the true random number, random number generation devices utilizing random physical phenomena for a random number seed, for example, such as a random telegraph signal (RTS) being a random current variation in a semiconductor device having a MIS (Metal Insulator Semiconductor) field effect transistor (FET) structure (MISFET) and 1/f noise being an ensemble of a plurality of RTSs have been invented (for example, JP-A 2007-304730(Kokai)).

The RTS is a current flowing through a channel region with variation with time due to a physical phenomenon such that resistance in the channel region changes by random capture and emission of a part of current carrier flowing through the channel region between a source electrode and a drain electrode due to trap in an insulating film, for example, in a MISFET.

In the random number generation device using the RTS, the random number is generated by sampling the RTS at a prescribed frequency. Therefore, in order to generate random numbers enhancing the security at high speed, it is important to increase the average frequency of the output variation from the MISFET, namely, the RTS.

### SUMMARY OF THE INVENTION

According to an aspect of the invention, there is provided a random number generation device including: a first transistor including: a first source region and a first drain region provided in a semiconductor layer; a first channel region provided between the first source region and the first drain region; a first insulating film provided on the first channel region and having a trap capturing and releasing a charge; and a first gate electrode provided on the first insulating film; a second transistor including: a second source region and a second drain region provided in the semiconductor layer; a second channel region provided between the second source region and the second drain region and made of a p-type semiconductor; a second insulating film provided on the second channel region; and a second gate electrode provided on the second insulating film, a first clock signal being inputted to the second gate electrode, one of the second source region and the second drain region being connected to one of the first source region and the first drain region; and a third transistor including: a third source region and a third drain region provided in the semiconductor layer; a third channel region provided between the third source region and the third drain region and made of an n-type semiconductor; a third insulating film provided on the third channel region; and a third gate electrode provided on the third insulating film, a second clock signal being inputted to the third gate electrode, a high/low relationship in a voltage of the second clock signal being inverted with respect to the first clock signal, one of the third source region and the third drain region being connected to other of the first source region and the first drain region, a tensile stress being applied in a gate length direction of the first transistor to at least one of the first channel region and the first insulating film, a tensile stress being applied in a gate length direction of the second transistor to at least one of the second channel region and the second insulating film, and a tensile stress being applied in a gate length direction of the third transistor to at least one of the third channel region and the third insulating film, or a compressive stress being applied in a gate length direction of the first transistor to at least one of the first channel region and the first insulating film, a compressive stress being applied in a gate length direction of the second transistor to at least one of the second channel region and the second insulating film, and a compressive stress being applied in a gate length direction of the third transistor to at least one of the third channel region and the third insulating film.

According to another aspect of the invention, there is provided a random number generation device including: a first source region; a first drain region; a first channel region provided between the first source region and the first drain region; a first insulating film provided on the first channel region and having a trap capturing and releasing a charge; and a first gate electrode provided on the first insulating film, a tensile or compressive stress being applied in a gate length direction to at least one of the first channel region and the first insulating film.

### BRIEF DESCRIPTION OF THE DRAWINGS

FIG. 1 is a schematic cross-sectional view for illustrating the configuration of a random number generation device according to a first embodiment of the invention;

FIGS. 2A and 2B are graph views illustrating characteristics of the random number generation device according to the first embodiment of the invention;

FIGS. 3A and 3B are graph views illustrating characteristics of a random number generation device of a comparative example;

FIG. 4 is a graph view illustrating characteristics of the random number generation device according to the first embodiment of the invention;

FIG. 5 is a circuit diagram illustrating the configuration of a random number generation device according to a second embodiment of the invention;

FIG. 6 is a schematic cross-sectional view for illustrating the configuration of the random number generation device according to the second embodiment of the invention;

FIG. 7 is a circuit diagram illustrating the configuration of a random number generation device according to a third embodiment of the invention;

FIG. 8 is a circuit diagram illustrating the configuration of a logic circuit used for the random number generation device according to the third embodiment of the invention;

FIG. 9 is a graph view illustrating characteristics of a random number generation device according to a fourth embodiment of the invention;

FIGS. 10A and 10B are schematic cross-sectional views illustrating the configuration of an insulating layer of a random number generation device according to an eighth embodiment of the invention;

FIG. 11 is a schematic cross-sectional view illustrating the configuration of a random number generation device according to a ninth embodiment of the invention;

FIG. 12 is a schematic plan view illustrating the configuration of the random number generation device according to the ninth embodiment of the invention; and

FIGS. 13A to 13C are schematic cross-sectional views in a process order illustrating a method for manufacturing a random number generation device according to a twelfth embodiment of the invention.

### DETAILED DESCRIPTION OF THE INVENTION

An embodiment of the invention will now be described with reference to the drawings.

The drawings are schematic or conceptualistic, and the relation between a thickness and a width of each portion and the coefficient ratio of dimensions among portions are not always limited to the same as the real one. Even when showing the same portion, each other's dimension and coefficient ratio may vary with the drawings.

Moreover, in the specification and each drawing, elements similar to those described above with reference to previous figures are marked with the same reference numerals and not described in detail as appropriate.

### First Embodiment

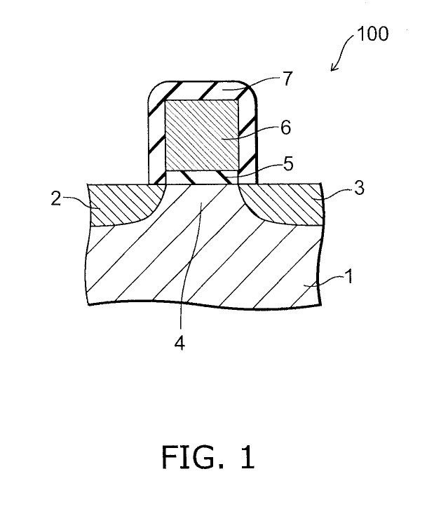

FIG. 1 is a schematic cross-sectional view for illustrating the configuration of a random number generation device according to a first embodiment of the invention.

As shown in FIG. 1, the random number generation device 100 according to the first embodiment of the invention includes a source region 2 provided in a semiconductor substrate (semiconductor layer) 1, a drain region 3, a channel region 4 provided between the source region 2 and the drain region 3, a first insulating film 5 provided on the channel region 4 and a gate electrode 6 provided on the first insulating film 5.

An insulating layer 7 is provided on a side of the first insulating film 5 and a side and a top surface of the gate electrode 6.

Like this, the random number generation device 100 has a MISFET structure.

The source region 2 and the drain region 3 are wired so that prescribed voltage can be applied externally, and through the wiring, the source region 2 and the drain region 3 are electrically connected. An interlayer insulating film not shown can be provided to cover the MISFET.

The gate electrode 6 can be based on low resistance polysilicon including impurities, or metal, for example.

The first insulating film 5 has electrical traps capturing and emitting a charge, namely, at least one of an electron and a hole randomly.

A stress is applied to at least one of the channel region 4 and the first insulating film 5 in a direction that a lattice spacing of a semiconductor crystal constituting the channel region 4 is expanded or reduced from a lattice spacing in the case where atoms in the semiconductor crystal are located at an equilibrium position at a practical operation temperature of the random number generation device in parallel with a current direction passing through the channel region 4. That is, the stress of tension or compression is applied in the direction of a gate length of the MISFET.

Herewith, for example, the atom position of the semiconductor crystal constituting the channel region 4 is displaced from the equilibrium position in parallel with the gate length direction, and the lattice spacing of the semiconductor crystal constituting the channel region 4 expands or reduces.

In the random number generation device 100 according to this embodiment, the substrate 1 and the channel region 4 can be based on (silicon) germanium (Si₁₋ₓGeₓ:0<x≦1), for example. That is, materials of silicon (Si) including germanium (Ge) and germanium (Ge) including no silicon (Si) in the case of x=1 can be used.

Si₁₋ₓGeₓ, in the case of x=1, is germanium (Ge) including no silicon (Si), however, in the specification, as follows, materials of silicon (Si) including germanium (Ge) and germanium (Ge) including no silicon (Si) in the case of x=1 are called ‘silicon germanium (Si₁₋ₓGeₓ: 0<x≦1)’.

The substrate 1 and the channel region 4 can also be based on silicon germanium (Si₁₋ₓGeₓ: 0<x≦1) formed on silicon (Si) with an enough thickness.

The source region 2 and the drain region 3 can be based on silicon carbon (Si_{1-z}C_{z}:0<z<1), for example.

At this time, a lattice constant of silicon carbon (Si_{1-z}C_{z}:0<z<1) used for the source region 2 and the drain region 3 is smaller than a lattice constant of silicon germanium (Si₁₋ₓGeₓ: 0<x≦1) used for the channel region 4, therefore, a silicon (Si) atom and a germanium (Ge) atom displace from an equilibrium position. That is, a stress expanding a lattice spacing of silicon germanium (Si₁₋ₓGeₓ: 0<x≦1) included in the channel region 4 in parallel with the gate length direction is generated. That is, the tensile stress expanding the lattice spacing is applied to the channel region 4. In some cases, the stress is also transmitted to the first insulating film 5, and the tensile stress expanding the lattice spacing of the channel 4 is applied to the first insulating film 5.

Hereby, as described below, an average frequency of a RTS of the MISFET can be higher.

Inventors performed an original experiment on the relationship between the stress expanding or reducing the lattice spacing of the semiconductor crystal constituting the channel of the MISFET and a time constant of the RTS. The content will be described below.

In the experiment, the uniaxial stress is applied to the channel region 4 and the first insulating film 5 in parallel with the gate length direction so as to change the lattice spacing of silicon (Si) included in the channel region 4, the stress at that time (strain amount of the channel region 4 and the first insulating film 5) is changed, and the time constant of the RTS was measured. A method for applying the stress changing the lattice spacing of the channel region 4 was based on a mechanically bending method of the whole of the substrate, and the stress changing the lattice spacing was varied by varying the bending amount. The bending amount is derived from the relationship between a thickness of the silicon substrate and a curvature or the like in a plane parallel to a major surface of the silicon substrate.

In this experiment, n-type silicon (Si) was used for the channel region 4, and hafnium silicon oxynitride (HfSiON) was used for the first insulating film 5.

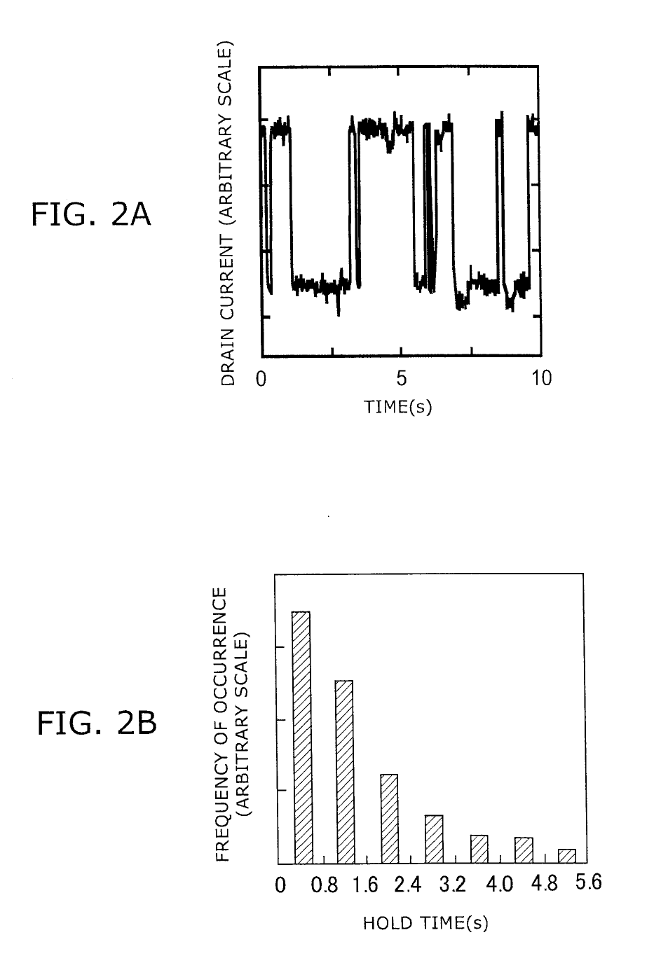

FIGS. 2A and 2B are graph views illustrating characteristics of the random number generation device according to the first embodiment of the invention.

That is, FIG. 2A illustrates the RTS, a horizontal axis represents time and a vertical axis represents a drain current. This figure illustrates a result where the stress amount applied to the channel region 4 and the first insulating film 5 is −0.0574% (compression strain).

FIG. 2B is a graph view derived from FIG. 2A and illustrating the relationship between hold time and a frequency of occurrence in a condition that a current value is small. The horizontal axis represents the hold time and the vertical axis represents the frequency of occurrence.

For convenience of description, here, the RTS having two levels varying between the two current values is exemplified.

As shown in FIG. 2A, roughly dividing, the drain current changes with time and has two conditions, the condition with the relatively small current value and with the relatively large current value. In addition to these two conditions, small changes of the current value are observed, but they are not dealt here.

When a carrier is captured in the first insulating film 5, resistance of the channel region 4 increases. Therefore, the current flowing through the channel region 4 decreases. On the other hand, when the carrier captured in the trap of the first insulating film 5 is released, the resistance of the channel region 4 decreases. That is, two conditions illustrated in FIG. 2A, the condition with the relatively small current value and the condition with the relatively large current value, correspond to the condition having the carrier captured in the trap of the first insulating film 5 and the condition having the carrier released from the trap of the first insulating film 5, respectively.

The hold times of the conditions with the relatively small current value and with the relatively large current value vary respectively. That is, the capture and release of the carrier by the trap of the first insulating film 5 are caused by tunneling of the carrier through the first insulating film 5 between the trap of the first insulating film 5 and the channel region 4. This tunneling does not have regularity in time and occurs randomly with time. Therefore, the hold times of the conditions with the relatively small current value and with the relatively large current value vary randomly, respectively. At this time, the random number can be generated by sampling the drain current with a prescribed frequency.

FIG. 2B can be derived from the result in FIG. 2A. That is, in FIG. 2A, for example, the hold time (time width) in the condition with the relatively small current value is obtained in a definite period and is divided into some ranges, and the frequency of an event occurrence of the hold time in every range is obtained. That is, the frequency of occurrence in every hold time is obtained. The result is illustratively shown in FIG. 2B.

As shown in FIG. 2B, the frequency of occurrence decreases with an increase of the hold time. The frequency of occurrence decreases exponentially with longer hold time. Here, the exponential distribution (Poisson distribution) of the hold time suggests that this RTS being observed is caused by a random physical phenomenon. Thus, since the frequency of occurrence of the hold time distributes exponentially, it is possible to define the time constant with respect to the distribution of the hold time.

That is, the value of each frequency of occurrence in a histogram illustrated in FIG. 2B is fitted by an exponential function (A×exp(−t/T)), where A is a proportionality constant, t is time and T is a time constant.

The time constant define like this is the reciprocal of the average frequency of output variation from the MISFET. That is, raising the average frequency of output variation from the MISFET is synonymous with decreasing the time constant. That is, it can be said that achievement of the high-speed random number generation device needs to decrease the time constant of the RTS of the output from the MISFET.

For example, from the relationship between the hold time and the frequency of occurrence illustrated in FIG. 2, the time constant is obtained to be 1.35 s.

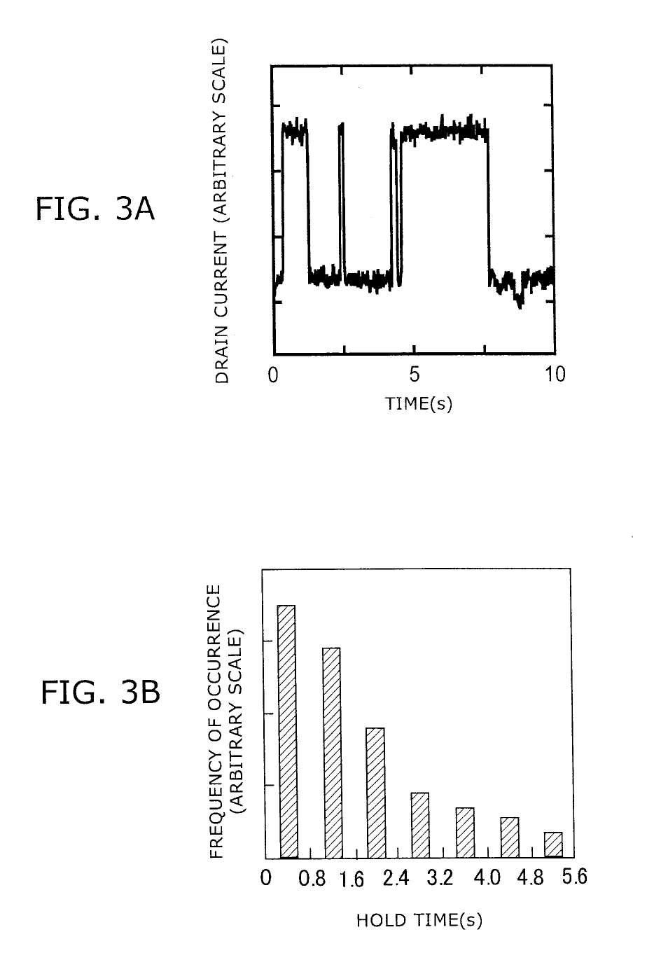

FIGS. 3A and 3B are graph views illustrating characteristics of a random number generation device of a comparative example.

That is, FIG. 3A illustrates the RTS, the horizontal axis represents time and the vertical axis represents the drain current. In this comparative example, the strain amount applied to the channel region 4 and the first insulating film 5 are 0%, that is, the result where the stress is not applied to the channel region 4 and the first insulating film 5 is shown.

FIG. 3B is a graph view derived from FIG. 2A and illustrating the relationship between the hold time and the frequency of occurrence in the condition that the current value is small. The horizontal axis represents the hold time and the vertical axis represents the frequency of occurrence.

As shown in FIG. 3A, also in the random number generation device of the comparative example, the drain current has two conditions, the condition with the relatively small current value and with the relatively large current value. The times holding these two conditions change. From the result, FIG. 3B is derived.

As illustrated in FIG. 3B, the time constant of the RTS of the comparative example is obtained to be 1.92 s. It is found that in the random number generation device of the comparative example, the time constant is larger in comparison with the random number generation device according to this embodiment illustrated in FIG. 2B.

Thus inventors have found that when the uniaxial stress is applied to the channel region 4 and the first insulating film 5 in parallel with the gate length direction so as to change the lattice spacing of silicon (Si) constituting the channel region 4, and the strain is applied to the channel region 4 and the first insulating film 5, the time constant of the RTS is decreased.

A result of the RTS obtained by changing the strain amount applied to the channel 4 and the first insulating film 5 is described below.

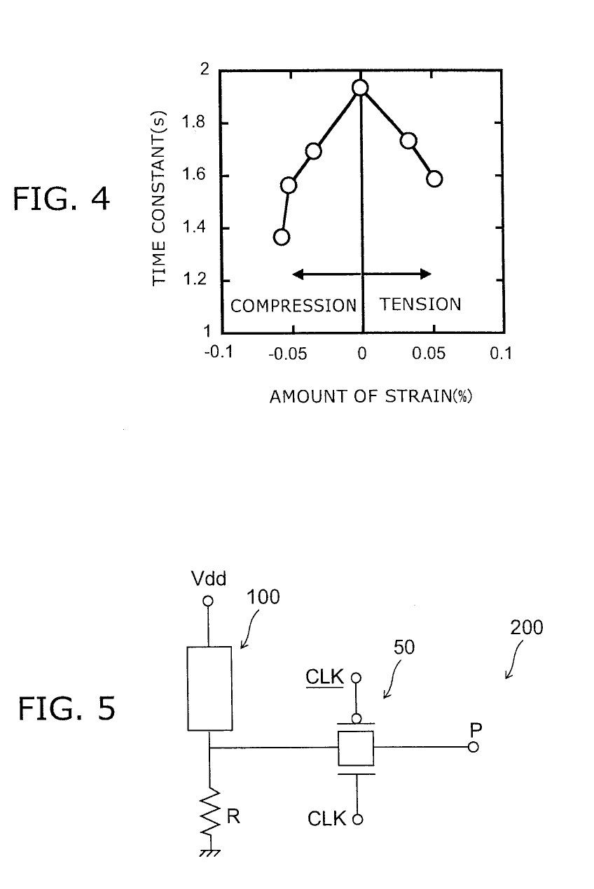

FIG. 4 is a graph view illustrating characteristics of the random number generation device according to the first embodiment of the invention.

In the figure, the horizontal axis represents the strain amount applied to the channel region 4 and the first insulating film 5 and the vertical axis represents the time constant of the RTS in the random number generation device.

As shown in FIG. 4, whether the stress applied to the channel region 4 and the first insulating film 5 is expansion or reduction stress, the time constant of the RTS is decreased.

In the figure, the case where the strain amount is −0.0574% corresponds to one example of this embodiment illustrated in FIGS. 2A and 2B, and the case where the strain amount is 0% corresponds to the comparative example illustrated in FIGS. 3A and 3B.

As shown in FIG. 4, by applying the uniaxial stress to the channel region 4 and the first insulating film 5 in parallel with the gate length direction so as to change the lattice spacing of silicon (Si) constituting the channel region 4, the time constant of the RTS can be decreased.

This embodiment of the invention is performed on the basis of the knowledge newly found. That is, in the random number generation device, in order to increase the speed of the random number generation, it is effective that the stress is applied to the channel region 4 and the first insulating film 5 in the direction that the lattice spacing of the semiconductor constituting the channel region 4 is expanded or reduced in parallel with the gate length direction.

Hereinafter, in the specification, ‘the stress in the direction that the lattice spacing of the semiconductor constituting the channel region 4 is expanded in parallel with the gate length direction’ is just called ‘expansion stress’. On the other hand, ‘the stress in the direction that the lattice spacing of the semiconductor constituting the channel region 4 is reduced in parallel with the gate length direction’ is just called ‘reduction stress’.

A mechanism of this phenomenon is estimated as follows.

For example, if the expansion stress or the reduction stress is applied to the channel region 4, a band structure of the semiconductor of the channel region 4 changes from an equilibrium state. Herewith, a condition in which the charge is easy to be released from the channel region 4 to the trap in the first insulating film 5 and the charge is easy to be accepted from the trap in the first insulating film 5 to the channel region 4 is possible to be obtained. As a result, the time constant of the RTS of the drain current is considered to be decreased.

For example, if the expansion stress or the reduction stress is applied to the first insulating film 5, the condition of the trap in the first insulating film 5 changes. At this time, a condition in which the trap in the first insulating film 5 is easy to release the charge and reversely the trap in the first insulating film 5 is easy to capture the charge is possible to be obtained. As a result, the time constant of the RTS of the drain current is considered to be decreased.

Herewith, it is considered that the result illustrated in FIG. 4 is obtained.

Therefore, in the random number generation device 100 according to this embodiment, the expansion stress or the reduction stress is configured to be applied to at least one of the channel region 4 and the first insulating film 5.

Thus, according to the random number generation device 100 according to this embodiment, the random number generation device enabling the average frequency of the RTS in the MISFET to be higher and generating the random number at a high speed can be provided.

In the random number generation device 100 according to this embodiment, as one method for applying the expansion stress or the reduction stress to at least one of the channel region 4 and the first insulating film 5, the channel region 4 is based on silicon germanium (Si₁₋ₓGeₓ: 0<x≦1) and the source region 2 and the drain region 3 are based on silicon carbon (Si_{1-z}C_{z}: 0<z<1). Herewith, a difference between both lattice constants is provided, and the stress is applied to the channel region 4 in the direction that the lattice spacing of silicon germanium (Si₁₋ₓGeₓ: 0<x≦1) included in the channel region 4 is expanded. This stress is also transmitted to the first insulating film 5 provided on the channel region 4 and the stress expanding the lattice spacing of silicon germanium (Si₁₋ₓGeₓ: 0<x≦1) included in the channel region 4 is applied to the first insulating film 5.

That is, in the above specific example, the expansion stress is generated by applying a material having a different lattice constant from the material used for the channel region 4 to the source region 2 and the drain region 3.

However, the invention is not limited thereto, but the expansion stress or the reduction stress can be generated by following various methods.

That is, a film generating the stress is used for a layer placed over the channel region 4 and the insulating film 5, thereby the expansion stress or the reduction stress can be generated. For example, the stress film placed over the channel region 4 and the first insulating film 5 can be based on the gate electrode 6, and by using the film generating the stress for the gate electrode 6, the expansion stress or the reduction stress is obtained.

Moreover, the expansion stress or the reduction stress can be generated by providing a stress liner (film generating the tensile or compressive stress) on the side face of the first insulating film 5 and the gate electrode 6. This stress liner can be based on the insulating layer 7, for example. That is, by using a material generating the tensile or compressive stress for the insulating layer 7, the expansion stress or the reduction stress can be obtained.

Furthermore, a biaxial stress in a plane parallel to the major surface of the substrate 1 is applied to the semiconductor layer serving as the channel region 4, and then anisotropy is provided to a shape of the source region 2, the drain region 3 and the channel region 4 in the plane parallel to the major surface of the substrate 1, and thereby the expansion stress or the reduction stress can be obtained.

By using the above method independently or in combination, the expansion stress or the reduction stress can be obtained.

The specific example of the above various methods will be described later.

Also by these methods, the expansion stress or the reduction stress can be applied to at least one of the channel region 4 and the first insulating film 5, and thereby the random number generation device decreasing the time constant of the RTS of the MISFET and generating the random number at a high speed can be provided.

### Second Embodiment

Next, a second embodiment will be described, in which the random number generation device 100 is used and the RTS signal generated in the random number generation device 100 is synchronized with a prescribed clock signal to be taken out.

FIG. 5 is a circuit diagram illustrating the configuration of a random number generation device according to the second embodiment of the invention. As shown in FIG. 5, the random number generation device 200 according to the second embodiment of the invention includes the random number generation device of the above embodiment and a pass gate 50 sampling the output of the random number generation device 100.

As shown in FIG. 5, the random number generation device 100 is provided with a resistor R, and the varying output current from the MISFET of the random number generation device 100 is converted to voltage. Then, this voltage is inputted to the pass gate 50.

For example, the path gate 50 can be based on combination of an n-type MOSFET and a P-type MOSFET, and clock signals having a prescribed frequency CLK (a first clock signal) and CLK (a second clock signal) are inputted to these MOSFET, respectively, and thereby the RTS generated in the random number generation device 100 is sampled and the random number is outputted to an output signal P. Here, CLK is a signal obtained by passing CLK through an inverter and having reversed high/low voltage with respect to CLK. For example, CLK is an inverted signal of CLK.

The pass gate 50 is based on both the n-type and p-type MOSFET. This is because of making an input signal pass through over the whole amplitude when the pass gate is turned on.

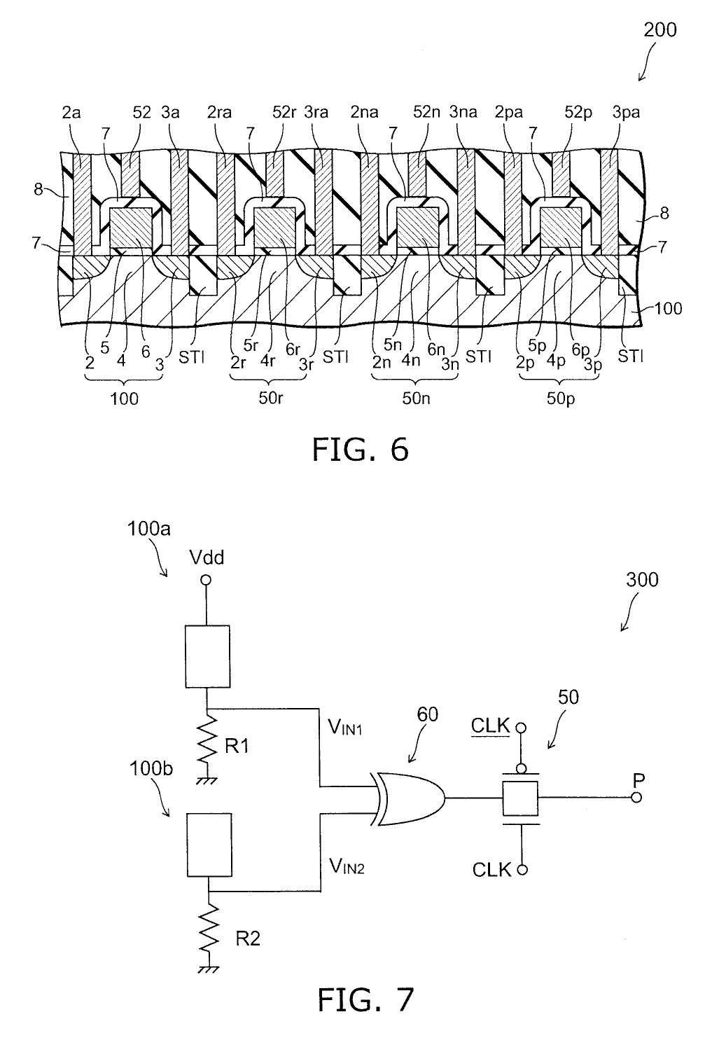

FIG. 6 is a schematic cross-sectional view for illustrating the configuration of the random number generation device according to the second embodiment of the invention.

As shown in FIG. 6, the random number generation device 200 according to the second embodiment of the invention includes the above random number generation device 100, and an n-type MOSFET 50n and a p-type MOSFET 50p serving as the pass gate 50. An n-type MOSFET 50r for resistor use is provided as the resistor R, for example.

As described previously, the random number generation device 100 (first transistor) includes the source region 2 (first source region), the drain region 3 (first drain region), the channel region 4 (first channel region) provided between them, the first insulating film 5 having the trap provided on the channel region 4, and the gate electrode 6 (first gate electrode) provided on the first insulating film 5. The insulating layer 7 is provided so as to cover them thereon.

The n-type MOSFET 50n (second transistor) serving as a part of the pass gate 50 includes a drain region 3n (second drain region 3n), a source region 2n (second source region 2n), a channel region 4n (second channel region 4n) provided between them and made of the p-type semiconductor, a second insulating film 5n provided on the channel region 4n, and a gate electrode 6n (second gate electrode 6n) provided on the second insulating film 5n.

Similarly, the p-type MOSFET 50p (third transistor) serving as another part of the pass gate 50 includes a drain region 3p (third drain region 3n), a source region 2p (third source region 2p), a channel region 4p (third channel region 4p) provided between them and made of the n-type semiconductor, a third insulating film 5p provided on the channel region 4p, and a gate electrode 6p (third gate electrode 6p) provided on the third insulating film 5p.

Moreover, the n-type MOSFET 50r (fourth transistor) for resistor use can also have a similar structure, and the n-type MOSFET 50r (fourth transistor) for resistor use includes a drain region 3r (fourth drain region 3r), a source region 2r (fourth source region 2r), a channel region 4r (fourth channel region 4r) provided between them, a fourth insulating film 5r provided on the channel region 4r, and a gate electrode 6r (fourth gate electrode 6r) provided on the fourth insulating film 5r.

In the specific example, the n-type MOSFET 50r for resistor use is used as the resistor R, however, the invention is not limited thereto, and various resistors other than resistors using transistors can be used. However, if the transistor is used as the resistor, the resistance value can be changed by the electrical signal, and hence the adjustment of characteristics in the random number generation becomes easy to be convenient.

As illustrated in FIG. 6, the random number generation device 100 generating the RTS, and the n-type MOSFET 50n and the p-type MOSFET serving as the pass gate 50 can be provided on the same substrate. The n-type MOSFET 50r for resistor use can also be provided on the same substrate as them.

The insulating layer 7 is provided over the n-type MOSFET 50n, the p-type MOSFET 50p and the n-type MOSFET 50r for resistor use.

For example, in the random number generation device 100, voltage Vdd (not shown) is applied to the source region 2 by a wiring 2a to the source region. First voltage (voltage value being adjustable externally) (not shown) is applied to the gate electrode 6 by a wiring 52. The drain region 3, the drain region 3r of the n-type MOSFET 50r for resistor use, the drain region 3n of the n-type MOSFET 50n of the pass gate and the drain region 3p of the p-type MOSFET 50p of the pass gate are electrically short-circuited by a wiring 3a, a wiring 3ra, a wiring 3na and a wiring 3p. The wiring is only shown partly.

In the n-type MOSFET 50r for resistor use, second voltage (voltage value being adjustable externally) (not shown) is applied to the gate electrode 6r by a wiring 52r. The source region 2r is grounded by a wiring 2ra.

In the n-type MOSFET 50n of the pass gate 50, the prescribed clock signal CLK (not shown) is inputted to the gate electrode 6n by a wiring 52n. The signal P is outputted from the source region 2n through a wiring 2na outputting the signal out.

In the p-type MOSFET 50p of the pass gate, the prescribed clock signal CLK (not shown) is inputted to the gate electrode 6n by a wiring 52p. The source region 2p is electrically short-circuited to the source region 2n by a wiring 2pa and the wiring 2na.

An interlayer insulating film 8 is provided over the random number generation device 100, the n-type MOSFET 50n, the p-type MOSFET 50p, and the n-type MOSFET 50r for resistor use and between them. Moreover, STI (Shallow Trench Isolation) or LOCOS (Local Oxidation of Silicon) is provided between each source region and drain region.

The configuration like this forms the random number generation device according to this embodiment having the circuit configuration illustrated in FIG. 5.

As previously described, in the random number generation device 100 generating the RTS, the expansion stress or the reduction stress is applied to the channel region 4 and the first insulating film 5.

The same stress is also applied to the channel region 4n and 4p and the first insulating film 5n and 5p of the n-type MOSFET 50n serving as the part of the pass gate 50 and the p-type MOSFET 50p serving as another part of the pass gate 50.

That is, the random number generation device 200 according to this embodiment includes: a first transistor 100 including: a semiconductor substrate 1; a first source region 2 and a first drain region 3 provided on the semiconductor substrate 1; a first channel region 4 provided between the first source region 2 and the first drain region 3; a first insulating film 5 provided on the first channel region 4 and having an electrical trap capturing and releasing an electron or a hole randomly; and a first gate electrode 6 provided on the first insulating film 5; a second transistor 50n including: a second source region 2n and a second drain region 3n provided on the semiconductor substrate 1; a second channel region 4n provided between the second source region 2n and the second drain region 3n and made of a p-type semiconductor; a second insulating film 5n provided on the second channel region 4n; and a second gate electrode 6n provided on the second insulating film 5n, one of the second source region 4n and the second drain region 3n being connected to one of the first source region 2 and the first drain region 3; and a third transistor 50p including: a third source region 2p and a third drain region 3p provided on the semiconductor substrate 1; a third channel region 4p provided between the third source region 2p and the third drain region 3p and made of an n-type semiconductor; a third insulating film 5p provided on the third channel region 4p; and a third gate electrode 6p provided on the third insulating film 5p, one of the third source region 2p and the third drain region 3p being connected to the other of the first source region 2 and the first drain region 3.

In the random number generation device 200, an expansion stress is applied in a gate length direction of the first transistor 100 to at least one of the first channel region 4 and the first insulating film 5, an expansion stress is applied in a gate length direction of the second transistor 50n to at least one of the second channel region 4n and the second insulating film 5n, and an expansion stress being applied in a gate length direction of the third transistor 50p to at least one of the third channel region 4p and the third insulating film 5p. Or a reduction stress is applied in a gate length direction of the first transistor 100 to at least one of the first channel region 4 and the first insulating film 5, a reduction stress is applied in a gate length direction of the second transistor 50n to at least one of the second channel region 4n and the second insulating film 5n, and a reduction stress is applied in a gate length direction of the third transistor 50p to at least one of the third channel region 4p and the third insulating film 5p.

With regard to the above stress applying method, as previously described in the first embodiment, various methods can be used, such as the method applying a material having a different lattice constant from the material used for the channel region 4 to the source region 2 and the drain region 3, the method using the film generating the stress as the layer placed on the channel region 4 and the first insulating film 5, the method providing the stress liner on the side face of the first insulating film 5 and the gate electrode 6, the method applying the biaxial stress to the channel region 4 to give the anisotropy to the shape of the source region 2, the drain region 3 and the channel region 4 in the plane parallel to the major surface of the substrate 1 or the like.

At this time, in the random number generation device 200, the stress in the random number generation device 100 generating the RTS, the stress in the n-type MOSFET included in the pass gate 50 and the stress in the p-type MOSFET included in the pass gate 50 can be the same kind of stress (expansion stress or reduction stress).

For example, when the expansion stress or reduction stress is given by the stress liner, the same film as the insulating layer 7 serving as the stress liner provided in the random number generation device 100 generating the RTS can be provided in the n-type MOSFET 50n and the p-type MOSFET 50p included in the pass gate 50.

That is, the random number generation device according to this embodiment can further comprise an insulating layer provided on the side face of the first gate electrode 6 and the side face of the first insulating film 5 and exerting an expansion stress on the first channel region 4 and the first insulating film 5, an insulating layer provided on the side face of the second gate electrode 6n and the side face of the second insulating film 5n and exerting an expansion stress on the second channel region 4n and the second insulting film 5n, and an insulating layer provided on the side face of the third gate electrode 6p and the side face of the third insulating film 5p and exerting an expansion stress on the third channel region 4p and the third insulating film 5p.

Or the random number generation device according to this embodiment can further comprise an insulating layer provided on the side face of the first gate electrode 6 and the side face of the first insulating film 5 and exerting a reduction stress on the first channel region 4 and the first insulating film 5, an insulating layer provided on the side face of the second gate electrode 6n and the side face of the second insulating film 5n and exerting a reduction stress on the second channel region 4n and the second insulting film 5n, and an insulating layer provided on the side face of the third gate electrode 6p and the side face of the third insulating film 5p and exerting a reduction stress on the third channel region 4p and the third insulating film 5p.

Generally, in the MOSFET, the stress liner may be used in order to improve mobility. Here, the expansion stress is applied to the n-type MOSFET and the reduction stress is applied to the p-type MOSFET.

On the contrary, in the random number generation device 200, the insulating layer 7 with the same property is used for either of n-type and p-type MOSFET included in the pass gate 50.

That is, in the random number generation device 200, for example, the insulating layer 7 used for the random number generation device 100 generating the RTS is provided for either n-type and p-type MOSFET included in the pass gate 50.

In the random number generation device 200 according to this embodiment, the need for reduction of the area of the n-type and p-type MOSFET included in the pass gate 50 is relatively low. Consequently, improvement of the mobility due to the stress is not needed significantly. Therefore, while by providing the insulating layer 7 with the same property, the mobility has a tendency to decrease in any of the n-type and the p-type MOSFET, it causes no practical problem. The insulating layer 7 serving as the film generating the tensile or compressive stress is used for both the n-type and p-type MOSFET included in the pass gate 50, thereby a manufacturing process becomes simple, and the random number generation device which can be manufactured with low cost and stably while demonstrating a practically enough performance can be provided.

According to the random number generation device 200 according to this embodiment, the practical random number generation device which can decrease the average time constant of the RTS of the MISFET, generate the random number at a high speed and can be manufactured with low cost and stably can be provided.

Here, a direction (assuming to be a first gate length direction) of the current passing through the channel region 4 of the MISFET (random number generation device 100) generating the RTS, a direction (assuming to be a second gate length direction) of the current passing through the channel region 4n of the n-type MOSFET 50n serving as a part of the pass gate 50, and a direction (assuming to be a third gate length direction) of the current passing through the gate channel 4p of the p-type MOSFET are arbitrary. For example, the second gate length direction may be either parallel or perpendicular to the first gate length direction, and an arbitrary angle can be allowed. Similarly, the third gate length direction may be either parallel or perpendicular to the first gate length direction, and an arbitrary angle can be allowed. When the second gate length direction or the third gate length direction is not parallel to the first gate length direction, the expansion stress or the reduction stress which are applied to the MISFET (random number generation device 100) generating the RTS is not always applied to the n-type or p-type MOSFET included in the pass gate 50.

### Third Embodiment

A random number generation device 300 according to a third embodiment of the invention is based on a plurality of the random number generation devices according to the embodiment of the invention described above and is provided with a logic circuit which generates a random number with a higher frequency than the frequency of the each random number generation device.

FIG. 7 is a circuit diagram illustrating the configuration of the random number generation device according to the third embodiment of the invention. As shown in FIG. 7, the random number generation device 300 according to the third embodiment of the invention is provided with a plurality of the random number generation devices 100 generating the RTS and the logic circuit 60 to which the outputs of the plurality of the device are inputted.

Random number signals are inputted to the logic circuit 60 and the logic circuit 60 has a function of generating a random signal with a higher speed than a plurality of random signals inputted. The logic circuit 60 can be based on a logic circuit of XOR (exclusive OR), for example. Moreover, a circuit combining a NOT (negation) circuit and an OR (logical add) circuit can be used. Moreover, it is not limited to thereto, a function generating the random signal with the higher speed than the plurality of random signals inputted only needs to be provided.

That is, the random number generation device 300 has two random number generation devices 100a, 100b generating the RTS. The random number generation devices 100a, 100b can be based on the random number generation device 100 according to the embodiment of the invention previously described.

In the random number generation device 300 illustrated in FIG. 7, for convenience of description, the case of two random number generation devices generating the random number is exemplified, however, in this embodiment, the number of the random number generation device generating the random number only needs to be plural, and the number is arbitrary. Moreover, a plurality of the logic circuits 60 whose inputs are connected to a plurality of the random number generation devices 100 can be provided and the outputs of the plurality of the logic circuits 60 can be inputted to another logic circuit 60.

As shown in FIG. 7, resistors R1, R2 are connected to each of the random number generation devices 100a, 100b generating the RTS, and thereby an output current varying with generation time in the random number generation devices 100a, 100b is converted to voltage. The plurality of converted voltage is inputted to the logic circuit 60.

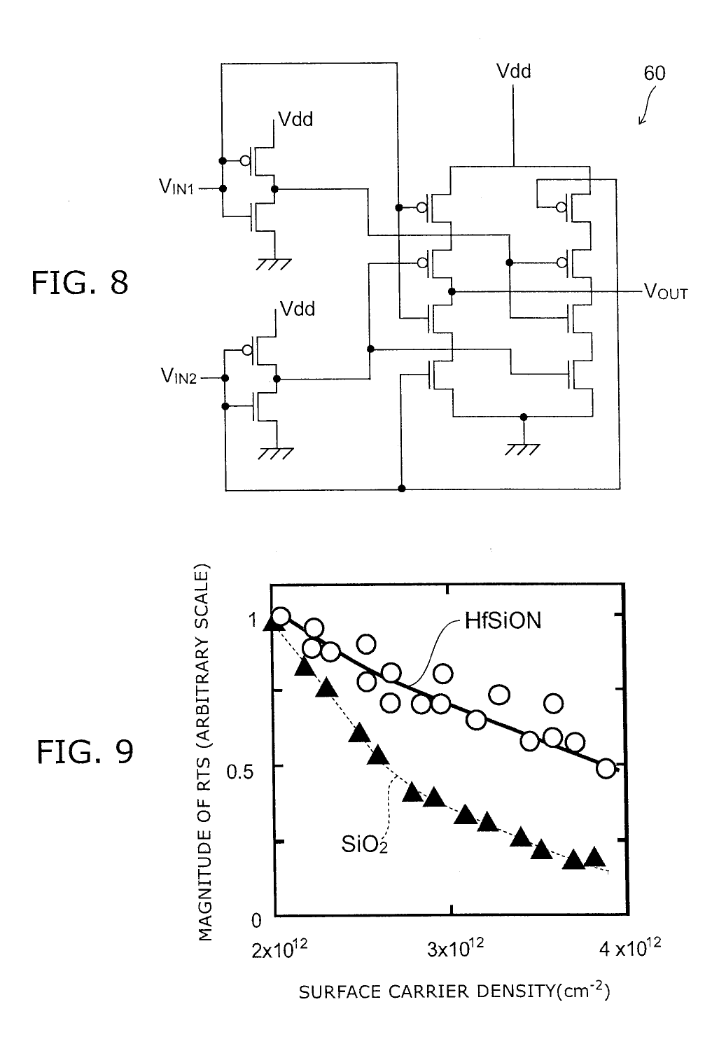

FIG. 8 is a circuit diagram illustrating the configuration of the logic circuit used for the random number generation device according to the third embodiment of the invention.

That is, FIG. 8 illustrates the case where the logic circuit 60 is the XOR logic circuit.

As shown in FIG. 8, in the logic circuit 60, computation results by the XOR of the signals inputted to inputs V_{IN1}, V_{IN2} are outputted to a V_{OUT}. Therefore, if the converted voltages of the output currents of the random number generation devices 100a, 100b generating the RTS are inputted to the inputs V_{IN1}, V_{IN2}, respectively, a random number with a smaller time constant than the random number generated in the random number generation devices 100a, 100b can be generated. Hence, by inputting the output to the pass gate 50, sampling by the prescribed frequency and generating the random number at a high speed can be achieved.

The above described plurality of the random number generation devices 100a, 100b, the logic circuit 60, and the pass gate 50 can be provided on the same substrate. However, this invention is not limited thereto, the logic circuit 60 may be provided on another substrate aside from the random number generation devices 100a, 100b. In the following, the case where the plurality of the random number generation devices 100a, 100b, the logic circuit 60 and the pass gate 50 are provided on the same substrate is described.

At this time, the stress in the same direction as the expansion stress or the reduction stress provided in the random number generation devices 100a, 100b can be provided in the logic circuit 60 and the pass gate 50.

For example, when the expansion stress or the reduction stress is provided by the stress liner in the random number generation devices 100a, 100b, an insulating layer film serving as the insulating layer 7 serving as the stress liner provided in the random number generation device 100a, 100b generating the RTS is provided in the n-type MOSFET 50n and the p-type MOSFET 50p included in the pass gate 50, and furthermore the insulating layer film serving as the insulating layer 7 provided in the plurality of the random number generation devices 100a, 100b can also be provided in the n-type MOSFET and the p-type MOSFET forming the logic circuit 60. That is, the same film as the insulating layer film serving as the insulating layer 7 being the film generating the expansion stress or the reduction stress is provided to the n-type and p-type MOSFET included in the logic circuit 60.

Thus, the same film as the insulating layer 7 provided in the random number generating device generating the RTS and serving as the film generating the expansion stress or the reduction stress is provided on the n-type and p-type MOSFET included in the pass gate 50 and the logic circuit 60, and hence the random number generation device which is easy to be manufactured with simple processes, raises the average frequency of the RTS and generates the high speed random number more effectively can be provided.

### Fourth Embodiment

In a random number generation device 104 according to a fourth embodiment, the first insulating film 5 is based on materials having a relative dielectric constant larger than a relative dielectric constant (3.9) of silicon dioxide (SiO₂) normally used as an insulating film in a semiconductor device.

The random number generation device 104 includes the source region 2 and the drain region 3 provided on the semiconductor substrate 1, the channel region 4 provided between the source region 2 and the drain region 3, the first insulating film 5 provided on the channel region 4 and the gate electrode 6 provided on the first insulating film 5. That is, the random number generation device 104 has the structure of the MISFET.

Similar to the first embodiment, the insulating layer 7 can be provided on the MISFET.

The first insulating film 5 has the electrical trap capturing and releasing the electron or the hole randomly. The relative dielectric constant of the first insulating film 5 is higher than 3.9. The first insulating film 5 is directly bonded over the channel region 4.

That is, in the random number generation device 104 according to this embodiment, the first insulating film 5 can be based on the materials having the relative dielectric constant larger than the relative dielectric constant (3.9) of silicon dioxide (SiO₂) normally used as the insulating film in the semiconductor device.

That is, in the random number generation device 104, at least part of the first insulating film 5 is provided adjacent to the channel region 4 and includes the insulating film having the relative dielectric constant higher than 3.9.

Except for the above, the random number generation device 104 is similar to the random number generation device according to the first embodiment, and hence the description is omitted.

The random number generation device 104 is directly provided with the first insulating film 5 over the channel region 4, and the insulating film 5 has the trap on the basis of a dangling bond which captures or releases the electron or the hole randomly with time.

As described previously, if the trap of the insulating film 5 captures the electron or the hole, in comparison with the case where the trap captures neither the electron nor the hole, the resistance of the channel region 4 increases and the amount of current flowing through the channel region 4 decreases. If the electron or the hole is released from the trap, the resistance of the channel region 4 decreases and the amount of current flowing through the channel region 4 increases. Capturing or releasing the electron or the hole by the trap occurs randomly, and hence the amount of current passing through the channel region 4 varies randomly. Therefore, a random current noise is outputted.

The capturing or releasing the electron or the hole in the traps in the first insulating film 5 can be performed effectively by providing the first insulating film 5 on the channel region 4 directly.

By setting the relative dielectric constant of the first insulating film 5 to a high value, in the random number generation device 104, as described below, a current variation is generated in a broad range of the gate voltage.

FIG. 9 is a graph view illustrating characteristics of the random number generation device according to the fourth embodiment of the invention.

The figure illustrates results of experiments performed originally by inventors with regard to the relationship between a magnitude of the RTS and a carrier density in the channel region 4 by using different materials for the first insulating film 5. The horizontal axis of the figure represents the carrier density in the channel region 4, and the vertical axis represents the magnitude of the RTS.

In the experiments, the first insulating film 5 is based on silicon dioxide (SiO₂) and hafnium silicon oxynitride (HfSiON), and the channel region 4, the source region 2 and the drain region 3 is formed of silicon (Si), and the gate electrode 6 made of polysilicon is formed on the first insulating film 5 having the trap.

As shown in FIG. 9, in any case where materials used for the first insulating film 5 is silicon dioxide (SiO₂) and hafnium silicon oxynitride (HfSiON), increasing the surface carrier density reduces a magnitude of the variation of the RTS current.

A tunneling phenomenon occurs most frequently, when the Fermi energy which is a representative energy of the carrier in the channel region 4 coincides energetically with the energy of the trap in the first insulating film 5. Therefore, the Fermi energy of the channel region 4 can be controlled by the gate voltage, and hence, generally, the frequency of the RTS is dependent on the gate voltage.

As shown in FIG. 9, it is relatively easily expected that as the carrier number in the channel region 4 increases, the magnitude of the variation of the current passing through the channel region 4 decreases.

However, it has not been known heretofore that a degree of the change in of the magnitude of the current variation passing through the channel region 4 corresponding to the increase of the carrier density varies with the material used for the first insulating film 5.

That is, as shown in FIG. 9, when the first insulating film having the trap is based on hafnium silicon oxynitride (HfSiON), in comparison with being based on silicon dioxide (SiO₂), the decrease of the amount of the current variation in the case where the carrier density in the channel region 4 increases is small.

The carrier density in the channel region 4 is proportional to the gate voltage, therefore when the first insulating film 5 having the trap is based on hafnium silicon oxynitride (HfSiON), in comparison with being based on silicon dioxide (SiO₂), the RTS with a large current variation can be generated in a broad range of the gate voltage.

The random number generation device 104 according to this embodiment is invented on the basis of the new knowledge illustrated in FIG. 9.

That is, in the random number generation device 104, the first insulating film 5 based on hafnium silicon oxynitride (HfSiON) can reduce the decrease of the amount of the current variation of the RTS, expand the gate voltage range generating the RTS and generate the random number, also in the case where the surface carrier density is high.

The decrease of the amount of the current variation in the case where the carrier density in the channel region 4 is high can be more reduced when the material used for the first insulating film 5 having the trap is hafnium silicon oxynitride (HfSiON) than when silicon dioxide (SiO₂) is used. The reason is thought that the screening effect by the carrier of an electrical influence on the channel region 4 is weaker in hafnium silicon oxynitride (HfSiON) than in silicon dioxide (SiO₂).

The electrical influence of the carrier captured by the trap of the first insulating film 5 on the channel region 4 is screened by the carrier in the channel region 4. The strength of the screening is inversely proportional to a dielectric constant which the carriers in the channel region 4 feel. Therefore, the screening effect is more decreased as the dielectric constant which the carriers in the channel region 4 feel is increased. Here, the dielectric constant which the carriers in the channel region 4 feel has an intermediate value between the dielectric constant of the channel region 4 and the dielectric constant of the first insulating film 5. Therefore, as the dielectric constant of the channel region 4 and the dielectric constant of the first insulating film 5 are increased, the screening effect is more decreased, and consequently, a large current variation is generated in a broad range of the gate voltage.

Thus, it is preferable that the dielectric constant of the first insulating film 5 is high. Thus, also in the case where the surface carrier density is high, the decrease of the amount of the current variation of the RTS can be reduced, the gate voltage range is expanded and the random number can be generated.

Similarly, it is preferable that the dielectric constant of the channel region 4 is high. Thus, also in the case where the surface carrier density is high, the decrease of the amount of the current variation of the RTS can be reduced. That is, it is preferable that the channel region 4 is based on a material having a dielectric constant higher than the dielectric constant of silicon generally used for the semiconductor device.

The channel region 4 can be based on silicon germanium (Si₁₋ₓGeₓ: 0<x≦1), for example.

Thus, setting the relative dielectric constant of the semiconductor included in the channel region 4 higher than 11.7 can reduce the decrease of the amount of the current variation of the RTS, expand the gate voltage range generating the RTS and generate the random number, also in the case where the surface carrier density is high.

As described previously, generally, the RTS is dependent on the gate voltage, and the gate voltage generated by the desired RTS varies with every MISFET. Therefore, as shown in the third embodiment, in the case of the random number generation device based on the plurality of random number generation device made of the MISFET and configured to input the output to the XOR logic circuit, the gate voltage of each MISFET is necessary to be adjusted to generate the desired RTS. At this time, if the range of the gate voltage generating the desired RTS is narrow, the gate voltage of the plurality of MISFET is necessary to be finely adjusted, and hence the adjustment is very difficult. On the contrary, the random number generation device 104 according to this embodiment has a broad range of the gate voltage generating the desired RTS, and hence an allowable range for the adjustment of the gate voltage of the MISFET expands, therefore the gate voltage adjustment of the plurality of the MISFET is simplified and the highly practical random number generation device is achieved.

Thus, the use of the random number generation device 104 according to this embodiment allows the RTS to be generated stably also in the case combining the plurality of the random number generation devices.

In the random number generation device 104 according to this embodiment, various methods generating the expansion stress or the reduction stress described in the first embodiment may be performed together.

Furthermore, also in the random number generation device 104 according to this embodiment, the random number generation device outputting the random signal by combining the random number generation device and the previously described pass gate 50 can be configured. Moreover, providing the plurality of the random number generation devices according to this embodiment and combining it with the logic circuit enable the random number generation device with a further high speed of the random number generation to be configured.

In the following fifth to ninth embodiments, various method for generating the expansion stress or the reduction stress are described.

### Fifth Embodiment

A fifth embodiment of the invention is another example which a method for obtaining the expansion stress by the method in which a material used for the source region 2 and the drain region 3 having a different lattice constant from the material used for the channel region 4 are used is applied.

That is, in a random number generation device 105 according to the fifth embodiment of the invention, the channel region 4 is based on silicon germanium (Si₁₋ₓGeₓ: 0<x≦1). On the other hand, the source region 2 and the drain region 3 are based on silicon germanium (Si_{1-y}Ge_{y}: 0<y≦1).

Here, germanium (Ge) concentrations in silicon germanium (Si₁₋ₓGeₓ: 0<x≦1) serving as the channel region 4 and silicon germanium (Si_{1-y}Ge_{y}: 0<y≦1) serving as the source region 2 and the drain region 3 satisfy the relationship of x>y. That is, the content of germanium (Ge) included in the channel region 4 is larger than the content of germanium (Ge) included in the source region 2 and the drain region 3.

By satisfying this relationship, the lattice constant of silicon germanium (Si₁₋ₓGeₓ: 0<x≦1) in the channel region 4 is expanded in parallel with the gate length direction. And, the expansion stress can be generated.

Thus, the random number generation device decreasing the time constant of the RTS of the MISFET and generating the random number at a high speed can be provided.

In the above, the expansion stress generated by the difference in the lattice constant of the materials used for the channel region 4 and the lattice constant of the material used for the source region 2 and the drain region 3 also exerts on the first insulating film 5, consequently the expansion stress is applied to the first insulating film 5.

That is, the stress such that the lattice spacing of the semiconductor included in the channel region 4 is expanded in parallel with the gate length direction is applied to at least one of the channel region 4 and the first insulating film 5.

In the random number generation device 105 according to this embodiment, another method of various methods generating the expansion stress or the reduction stress described in the first embodiment may be performed simultaneously.

Moreover, also in the random number generation device 105 according to this embodiment, the random number generation device described in the second embodiment and outputting the random number by combining the random number generation device and the previously described pass gate 50 can be configured.

Moreover, providing the plurality of the random number generation devices according to this embodiment and combining it with the logic circuit enable the random number generation device having a further high frequency of the random number generation and described in the third embodiment to be configured.

### Sixth Embodiment

A sixth embodiment of the invention is another example which a method for obtaining the reduction stress by the method in which a material used for the source region 2 and drain region 3 having a different lattice constant from the material used for the channel region 4 are used is applied.

That is, in a random number generation device 106 according to the sixth embodiment of the invention, the channel region 4 is based on silicon germanium (Si₁₋ₓGeₓ: 0<x≦1). On the other hand, the source region 2 and the drain region 3 are based on silicon germanium (Si_{1-y}Ge_{y}: 0<y≦1).

Here, germanium (Ge) concentrations in silicon germanium (Si₁₋ₓGeₓ: 0<x≦1) serving as the channel region 4 and silicon germanium (Si_{1-y}Ge_{y}: 0<y≦1) serving as the source region 2 and the drain region 3 satisfy the relationship of x<y. That is, the content of germanium (Ge) included in the channel region 4 is smaller than the content of germanium (Ge) included in the source region 2 and the drain region 3.

By satisfying this relationship, the lattice constant of silicon germanium (Si₁₋ₓGeₓ: 0<x≦1) in the channel region 4 is decreased in parallel with the gate length direction. And, the reduction stress can be generated.

Thus, the random number generation device decreasing the time constant of the RTS of the MISFET and generating the random number at a high speed can be provided.

In the random number generation device 106 according to this embodiment, another method of various methods generating the expansion stress or the reduction stress described in the first embodiment may be performed simultaneously.

Moreover, also in the random number generation device 106 according to this embodiment, the random number generation device described in the second embodiment and outputting the random number by combining the random number generation device and the previously described pass gate 50 can be configured.

Moreover, providing the plurality of the random number generation devices and combining it with the logic circuit enable the random number generation device having a further high speed of the random number generation and described in the third embodiment to be configured.

In the above, the reduction stress generated by the difference in the lattice constant of the material used for the channel region 4 and the lattice constant of the material used for the source region 2 and the drain region 3 also exerts on the first insulating film 5, consequently the reduction stress is applied to the first insulating film 5.

That is, the stress such that the lattice spacing of the semiconductor included in the channel region 4 is decreased in parallel with the gate length direction is applied to at least one of the channel region 4 and the first insulating film 5.

As illustrated in the above fifth and sixth embodiments, by making the germanium (Ge) concentration in silicon germanium (Si₁₋ₓGeₓ: 0<x≦1) serving as the channel region 4 different from the germanium (Ge) concentration in silicon germanium (Si_{1-y}Ge_{y}: 0<y≦1) serving as the source region 2 and the drain region 3, the expansion stress or the reduction stress can be caused to be generated and can be applied to at least one of the channel region 4 and the first insulating film 5. Thus, the time constant of the RTS of the MISFET can be decreased and the random number generation device generating the random number at a high speed can be provided.

### Seventh Embodiment

In a random number generation device according to a seventh embodiment of the invention, the expansion stress is obtained by using a film having a stress for the film placed on the channel region 4 and the first insulating film 5, for example.

That is, in the random number generation device 107 according to this embodiment, the gate electrode 6 provided on the first insulating film 5 in the random number generation device 100 according to this embodiment illustrated in FIG. 1 is based on polysilicon added with arsenic (As). In this case, a phenomenon which the stress is applied to circumference when silicon turned into amorphous during implantation of arsenic (As) is changed to polysilicon in a manufacturing process is utilized.

Utilizing this phenomenon enables the expansion stress to be generated and the expansion stress is applied to the channel region 4 and the first insulating film 5.

Thus, the random number generation device decreasing the time constant of the RTS of the MISFET and generating the random number at a high speed can be provided.

In the random number generation device 107 according to this embodiment, another method of various methods generating the expansion stress or the reduction stress described in the first embodiment may be performed simultaneously.

Moreover, also in the random number generation device 107 according to this embodiment, the random number generation device described in the second embodiment and outputting the random number by combining the random number generation device and the previously described pass gate 50 can be configured.

Moreover, providing the plurality of the random number generation devices and combining it with the logic circuit enable the random number generation device having a further high speed of the random number generation and described in the third embodiment to be configured.

### Eighth Embodiment

In a random number generation device 108 according to an eighth embodiment of the invention, the expansion stress or the reduction stress is obtained by the stress liner.

That is, in the random number generation device 108 according to this embodiment, by suitably selecting the material used for the insulating layer 7 provided so as to cover the gate electrode 6 and a film formation condition in the random number generation device 100, the expansion stress or the reduction stress is applied to the channel region 4 and the first insulating film 5, for example.

For example, the insulating layer 7 can be based on an insulating film such as SiN and Diamond-like Carbon. When SiN is used, one of the expansion stress and the reduction stress can be applied by devising the condition. When Diamond-like Carbon is used, the reduction stress can be applied.

The stress liners like these only need to be provided at least on the side face of the gate electrode 6 and the side face of the first insulating film 5. That is, in the structure illustrated in FIG. 1, the insulating layer 7 capable of having a function of the stress liner is provided on the upper surface of the gate electrode 6, the side face of the gate electrode 6, the side face of the first insulating film 5, the source region 2 and the drain region 3, however the stress liner, namely, the insulating film generating the tensile or compressive stress only needs to be provided at least on the side face of the gate electrode 6 and the side face of the first insulating film 5. Thus, the expansion stress or the reduction stress can be generated and can be applied to at least one of the channel region 4 and the first insulating film 5.

Thus, the random number generation device decreasing the time constant of the RTS of the MISFET and generating the random number at a high speed can be provided.

In the random number generation device 108 according to this embodiment, another method of various methods generating the expansion stress or the reduction stress described in the first embodiment may be performed simultaneously.

Moreover, also in the random number generation device 108 according to this embodiment, the random number generation device described in the second embodiment and outputting the random number by combining the random number generation device and the previously described pass gate 50 can be configured.

Moreover, providing the plurality of the random number generation devices and combining it with the logic circuit enable the random number generation device having a further high speed of the random number generation and described in the third embodiment to be configured.

Here, a thickness of the above insulating layer 7 can be set not to be excessively thick in comparison with a height of a protrusion formed by the first insulating film 5 and the gate electrode 6 provided thereon. That is, if the insulating layer 7 is too thick, it is difficult to apply the desired stress on the channel region 4 and the first insulating film 5.

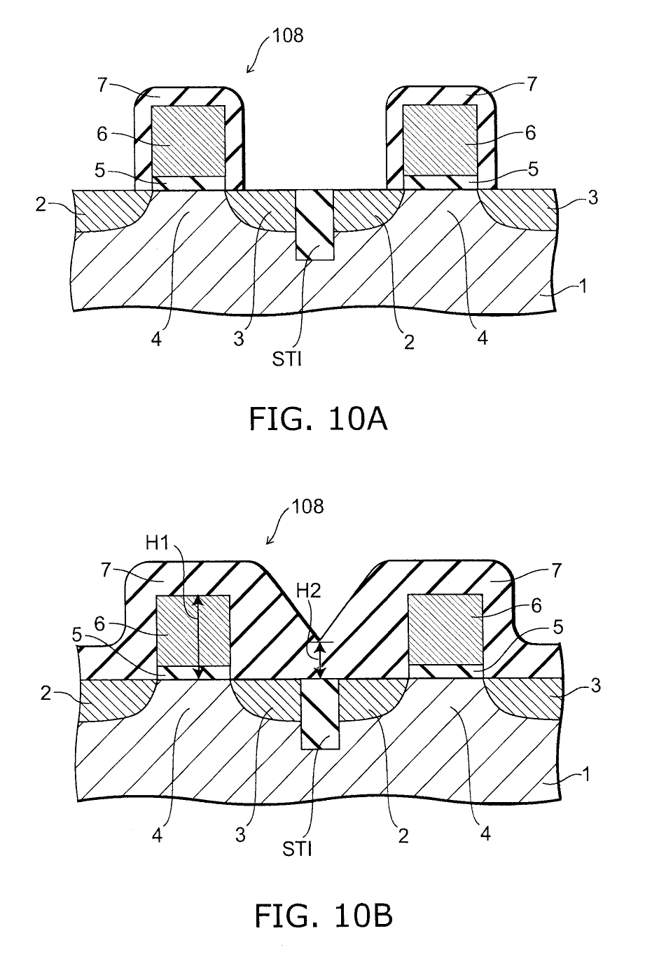

FIGS. 10A and 10B are schematic cross-sectional views illustrating the configuration of the insulating layer of the random number generation device according to the eighth embodiment of the invention.

FIG. 10A illustrates a case where the insulating layer 7 of the random number generation device is relatively thin and FIG. 10 B illustrates a case where the layer is relatively thick.

As shown in FIG. 10A, when the insulating layer 7 of the random number generation device is relatively thin, the insulating layer 7 is provided on the side face of the gate electrode 6 and the first insulating film 5 in a shape along the shape of the gate electrode 6 and the first insulating film 5, and thereby the desired stress can be applied to the channel region 4 and the first insulating film 5.

As shown in FIG. 10B, when the insulating layer 7 of the random number generation device is relatively thick, the insulating layer 7 is leveled to be formed. At this time, as shown in the figure, a height H2 of the insulating layer 7 at the position where a height (distance in thickness direction) of the insulating layer 7 from the substrate 1 becomes minimum needs to be lower than a height H1 of the gate electrode 6 of the random number generation device 100. If the height H2 of the insulating layer 7 is the height H1 of the gate electrode 6 or more, the desired stress becomes difficult to be applied to the channel region 4 and the first insulating film 5. That is, the insulating layer 7 is provided so as not to be excessively thick.

Thus, in the random number generation device 108 according to this embodiment, the insulating layer 7 serving as the stress liner with the suitable thickness is provided and the stress of the insulating layer 7 can be effectively applied to the channel region 4 and the first insulating film 5. Hence the random number generation device decreasing the time constant of the RTS of the MISFET and generating the random number at a high speed can be provided.

### Ninth Embodiment

A random number generation device 109 according to a ninth embodiment of the invention is an example which a method for obtaining the expansion stress by providing the biaxial stress on the channel region 4 and providing the anisotropy to a shape of the source region 2, the drain region 3 and the channel region 4 in the plane parallel to the major surface of the substrate 1 is applied.

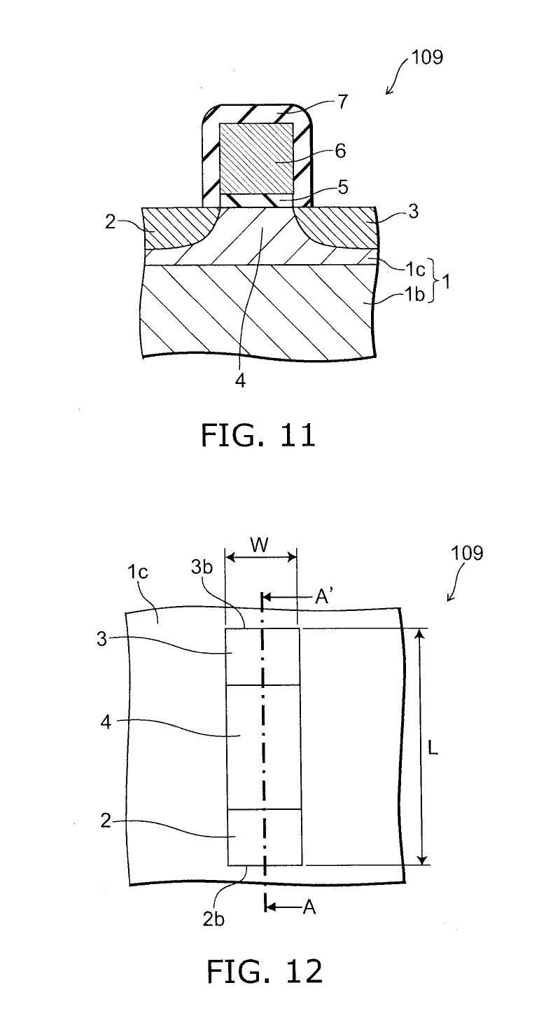

FIG. 11 is a schematic cross-sectional view illustrating the configuration of the random number generation device according to the ninth embodiment of the invention.

FIG. 12 is a schematic plan view illustrating the configuration of the random number generation device according to the ninth embodiment of the invention.

That is, FIG. 11 is an A-A′ line cross-sectional view of FIG. 12. In FIG. 12, the first insulating film 5, the gate electrode 6 and the insulating layer 7 are omitted.

As shown in FIG. 11, in the random number generation device 109 according to this embodiment, the substrate 1 is based on strained silicon (Si) is formed on silicon germanium (Si₁₋ₓGeₓ: 0<x≦1) 1b. That is, the channel region 4 is based on the strained silicon (Si) 1c formed on the silicon germanium (Si₁₋ₓGeₓ: 0<x≦1) 1b.

In FIG. 11, the substrate 1 may be based on the strained silicon (Si) 1c formed on the silicon germanium (Si₁₋ₓGeₓ: 0<x≦1) 1b having an enough thickness formed on a silicon (Si) substrate (not shown). That is, the channel region 4 may be based on the strained silicon (Si) 1c formed on the silicon germanium (Si₁₋ₓGeₓ: 0<x≦1) 1b having an enough thickness formed on a silicon (Si) substrate (not shown).

By adopting this configuration, due to the lattice constant difference between silicon germanium (Si₁₋ₓGeₓ: 0<x≦1) and silicon (Si), the silicon (Si) atom of the silicon (Si) 1c formed on the silicon germanium (Si₁₋ₓGeₓ: 0<x≦1) 1b in the substrate 1 displaces from the equilibrium position, and the biaxial tensile stress in the plane in parallel with the major surface of the substrate 1 is applied in the plane of the strained silicon (Si) 1c.

Then, as shown in FIG. 12, the anisotropy is provided to a shape of the source region 2, the drain region 3 and the channel region 4 in the plane parallel to the major surface of the substrate 1.

Here, as shown in FIG. 12, a distance from an end 3b of the drain region 3 opposite to an interface adjacent to the channel region 4 to an end 2b of the source region 2 opposite to an interface adjacent to the channel region 4 is assumed to be called a vertical length L of the MISFET. A length of the channel region 4 in a direction orthogonal to a direction along the above vertical length L is assumed to be called a horizontal length W of the MISFET.

The vertical length L and the horizontal length W can be defined by the boundary between, STI or LOCOS provided around the source region 2, the drain region 3 and the channel region 4, and the source region 2, the drain region 3 and the channel region 4.

In the random number generation device 109 according to this embodiment, the vertical length L of the MISFET can be set to be longer than the horizontal length W of the MISFET.

That is, L and W can be designed so as to satisfy the relationship of L>a1×W (a1 is a constant of 1 or more). Thus, the biaxial stress generated by the difference of the lattice constants can be changed to the uniaxial stress in a direction along the vertical length L.

The constant a1 changes with an impurity concentration.

Thus, by providing the plane shape of the MISFET with the anisotropy, the expansion stress can be generated, and can be applied to at least one of the channel region 4 and the first insulating film 5.

Hence, the random number generation device 109 according to this embodiment can provide the random number generation device which decreases the time constant of the RTS of the MISFET and generates the random number at a high speed.

In the random number generation device 109 according to this embodiment, another method of various methods generating the expansion stress described in the first embodiment may be performed simultaneously.

Moreover, also in the random number generation device 109 according to this embodiment, the random number generation device described in the second embodiment and outputting the random number by combining the random number generation device and the previously described pass gate 50 can be configured.

Moreover, providing the plurality of the random number generation devices and combining it with the logic circuit enable the random number generation device having a further high speed of the random number generation and described in the third embodiment to be configured.

In the random number generation device 109 according to this embodiment, as described in the fourth embodiment, the method based on the material having the high relative dielectric constant as the first insulating film 5 can be applied.

That is, the insulating film 5 has the trap on the basis of a dangling bond which captures or releases the electron or the hole randomly with time. The first insulating film 5 can be based on the materials having the relative dielectric constant larger than the relative dielectric constant (3.9) of silicon dioxide (SiO₂) normally used as the insulating film in the semiconductor device, for example, hafnium silicon oxynitride (HfSiON). As shown in FIG. 11, also in the random number generation device 109 according to this embodiment, the first insulating film 5 is directly provided on the channel region 4.

### Tenth Embodiment

A random number generation device 110 according to a tenth embodiment of the invention is an example which a method for obtaining the reduction stress by providing the biaxial stress on the channel region 4 and providing the anisotropy to a shape of the source region 2, the drain region 3 and the channel region 4 in the plane parallel to the major surface of the substrate 1 is applied.

The random number generation device 110 according to this embodiment (not shown) has an inverted arrangement of the silicon (Si) 1c and the silicon germanium (Si₁₋ₓGeₓ: 0<x≦1) 1b in the random number generation device 109 according to the ninth embodiment illustrated in FIG. 11 and FIG. 12. The configuration except for that can be similar to the random number generation device 109.

That is, in the random number generation device 110 according to this embodiment, the substrate 1 is based on the silicon germanium (Si₁₋ₓGeₓ: 0<x≦1) 1b formed on the silicon (Si) 1c. That is, the channel region 4 is based on the silicon germanium (Si₁₋ₓGeₓ: 0<x≦1) 1b formed on the silicon (Si) 1c.

By adopting this configuration, due to the lattice constant difference between silicon (Si) and silicon germanium (Si₁₋ₓGeₓ: 0<x≦1), the silicon (Si) atom and the germanium (Ge) atom of the silicon germanium (Si₁₋ₓGeₓ: 0<x≦1) 1b formed on the silicon (Si) 1c in the substrate 1 displace from the equilibrium position, and the biaxial compressive stress in the plane in parallel with the major surface of the substrate 1 is applied in the plane of the silicon germanium (Si₁₋ₓGeₓ: 0<x≦1) 1b.

Here, similar to the random number generation device 109 illustrated in FIG. 12, in the random number generation device 110 according to this embodiment, the distance from the end 3b of the drain region 3 opposite to the interface adjacent to the channel region 4 to the end 2b of the source region 2 opposite to the interface adjacent to the channel region 4 is assumed to be called the vertical length L of the MISFET. The length of the channel region 4 in the direction orthogonal to the direction along the above vertical length L is assumed to be called the horizontal length W of the MISFET.

In the random number generation device 110 according to this embodiment, the vertical length L of the MISFET can be set to be longer than the horizontal length W of the MISFET.

That is, L and W can be designed so as to satisfy the relationship of L>a2×W (a2 is a constant of 1 or more). Thus, the biaxial stress generated by the difference of the lattice constants can be changed to the uniaxial stress in the direction along the vertical length L.

The constant a2 changes with the impurity concentration.

Thus, by providing the plane shape of the MISFET with the anisotropy, the reduction stress can be generated, and can be applied to at least one of the channel region 4 and the first insulating film 5.

Hence, the random number generation device 110 according to this embodiment can provide the random number generation device which decreases the time constant of the RTS of the MISFET and generates the random number at a high speed.

In the random number generation device 110 according to this embodiment, the method described in the sixth embodiment for obtaining the reduction stress by the method in which the channel region 4, the source region 2 and the drain region 3 are based on materials having a different lattice constant may be performed simultaneously.

That is, germanium (Ge) concentrations in silicon germanium (Si₁₋ₓGeₓ: 0<x≦1) serving as the channel region 4 and silicon germanium (Si_{1-y}Ge_{y}: 0<y≦1) serving as the source region 2 and the drain region 3 can satisfy the relationship of x<y. That is, the content of germanium (Ge) included in the channel region 4 can be smaller than the content of germanium (Ge) included in the source region 2 and the drain region 3.

By configuring like this, the reduction stress can be generated, and the reduction stress due to the above anisotropy, together with the reduction stress due to the lattice constant difference, can be synergistically used, hence a larger reduction stress can be generated and applied to at least one of the channel region 4 and the first insulating film 5.

Thus, the random number generation device decreasing further the time constant of the RTS of the MISFET and generating the random number at a high speed and more effectively can be provided.

In the random number generation device 110, the method described in the eighth embodiment for obtaining the reduction stress by the stress liner can be applied.

That is, the insulating layer 7 can be based on a tensile insulating film of SiN, for example. The tensile insulating layer 7 can generate the reduction stress. Thus, the reduction stress due to the above anisotropy, together with the reduction stress due to the stress liner, is worked synergistically, and a larger reduction stress can be generated and can be applied to at least one of the channel region 4 and the first insulating film 5.

Thus, the random number generation device decreasing further the time constant of the RTS of the MISFET and generating the random number at a high speed can be provided.

Also in the random number generation device 110, as described in the fourth embodiment, the method based on the material having the high relative dielectric constant as the first insulating film 5 can be applied.

That is, the insulating film 5 has the trap on the basis of a dangling bond which captures or releases the electron or the hole randomly with time. The first insulating film 5 can be based on the materials having the relative dielectric constant larger than the relative dielectric constant (3.9) of silicon dioxide (SiO₂) normally used as the insulating film in the semiconductor device, for example, hafnium silicon oxynitride (HfSiON). Also in the random number generation device 110 according to this embodiment, the first insulating film 5 is directly provided on the channel region 4.

As described above in the ninth and tenth embodiments, a combination of various methods generating the expansion stress or a combination of various methods generating the reduction stress can be performed.

However, the invention is not limited thereto. That is, the method and the structure generating the expansion stress and the method and the structure generating the reduction stress can be mixed to be used. That is, when the combination of the various methods and structures described above is used, in a comprehensive manner, the expansion stress or the reduction stress only needs to be generated to be applied to the channel region 4 or the first insulating film 5.

For example, when the method generating the large expansion stress and the method generating the small reduction stress are simultaneously performed, as a result of their difference, the expansion stress is generated and applied to one of the channel region 4 and the first insulating film 5. Reversely, when the method generating the small expansion stress and the method generating the large reduction stress are simultaneously performed, as a result of their difference, the reduction stress is generated and applied to at least one of the channel region 4 and the first insulating film 5. Also hereby, the random number generation device raising the average frequency of the MISFET more effectively and generating the high speed random number more effectively can be provided.

However, as described previously, performing a combination of methods generating the stress in the same direction (expansion or reduction) is preferable because a synergy effect is brought out.

Furthermore, also in the random number generation device 110 according to this embodiment, the random number generation device described in the second embodiment and outputting the random number by combining the random number generation device and the previously described pass gate 50 can be configured.

Moreover, providing the plurality of the random number generation devices and combining it with the logic circuit enable the random number generation device having a further high speed of the random number generation and described in the third embodiment to be configured.

### Eleventh Embodiment

In a random number generation device 111 according to an eleventh embodiment of the invention, the main carriers in a current generating the RTS are set to be holes.

That is, in the random number generation device 111 according to this embodiment, the channel region 4 can be based on n-type silicon germanium (Si₁₋ₓGeₓ: 0<x≦1) containing arsenic (As) or phosphor (P) as impurities, for example.

The source region 2 and the drain region 3 can be based on silicon carbon (Si_{1-z}C_{z}: 0<z<1) containing boron (B) as an impurity so as to be p-type semiconductor, for example.

In the random number generation device 111, if the energy in the channel region 4 is modulated by the gate voltage and the holes are caused to be able to exist in the channel region 4, current mainly made of holes passes through between the source region 2 and the drain region 3. Thus, it is preferable that the carriers of the current are holes. The reason is described below.

As described above, in the random number generation device 111 according to this embodiment, noise is generated by random capture and release of the hole in the channel region 4 by the electrical trap capturing the electron or the hole in the first insulating film 5. Here, the hole comes and goes from the trap to channel region 4 by tunneling through the first insulating film 5. Increasing the frequency of this tunneling phenomenon in a unit time increases the random number generation speed.

Generally, the frequency of the tunneling phenomenon in a unit time is determined by a product of a success probability of tunneling in one trial of the tunneling by one carrier and a number of the tunneling trial in a unit time. That is, as the number of the tunneling trial in a unit time is increased and as the success probability of the tunneling is increased, the frequency of the tunneling phenomenon in a unit time more increases.

First, the trial number of the tunneling in a unit time is described.

As described above, the tunneling phenomenon occurs most frequently when the energy of the trap in the first insulating film 5 having the trap coincides with the Fermi energy of the channel region 4. Therefore, in order to increase the trial number of the tunneling in a unit time, it is desired to make a condition that a greater number of carriers having the energy near to the energy of the trap in the first insulating film 5 exist in the channel region 4, and a greater number of carriers try to tunnel. Generally, a greater number of carriers in a certain energy can exist (density of state is high) in a valence band relative to a conduction band in a semiconductor, and hence a greater number of holes can exist at the same energy. Therefore, the tunneling trial number in a unit time increases in the case where the carriers are holes than in the case where the carriers are electrons.

Next, the success probability of the tunneling is described.

The more the insulating film 5 having the trap acts as an energetically lower barrier for the carriers in the channel region 4, the more the success probability of the tunneling increases. Generally, the magnitude of the energy acting as the barrier for the carrier varies depending on a kind of the semiconductor crystal constituting the channel region 4, a kind of the first insulating film 5 having the trap, and whether the carrier is the electron or the hole. For example, in a combination of hafnium oxynitride (HfSiON) on silicon (Si), when the content of nitrogen (N) is low, hafnium oxynitride (HfSiON) acts as the energetically lower barrier for the hole than for the electron. Thus, also from the viewpoint of the success probability of the tunneling, the carrier is preferred to be the hole.

Thus, from the both viewpoints of the trial number of the tunneling in a unit time and the success probability of the tunneling, the case where the carrier is the hole is more advantageous than the case of the electron. If the carrier is the hole, the frequency of the tunneling phenomenon in a unit time becomes higher.

Thus, in the random number generation device 111 according to this embodiment, it is preferred that the carrier is the hole, and hence the frequency of the tunneling phenomenon in a unit time can be higher, and the random number generation device decreasing the time constant of the RTS of the MISFET and generating the random number at a high speed can be provided.

In the random number generation device 111 according to this embodiment, another method of various methods generating the expansion stress or the reduction stress described in the first embodiment may be performed simultaneously.

Moreover, also in the random number generation device 111 according to this embodiment, the random number generation device described in the second embodiment and outputting the random number by combining the random number generation device and the previously described pass gate 50 can be configured.

Moreover, providing the plurality of the random number generation devices and combining it with the logic circuit enable the random number generation device having a further high speed of the random number generation and described in the third embodiment to be configured.

### Twelfth Embodiment

In a random number generation device 112 according to a twelfth embodiment of the invention, the method using the lattice constant difference of the first embodiment, the method using the high relative dielectric constant material for the first insulating film 5 of the fourth embodiment, the method using the stress liner of the sixth embodiment and the method based on the hole as the carrier according to the eleventh embodiment described above are combined to be performed.

In the following, first, a method for manufacturing the random number generation device 112 is described.

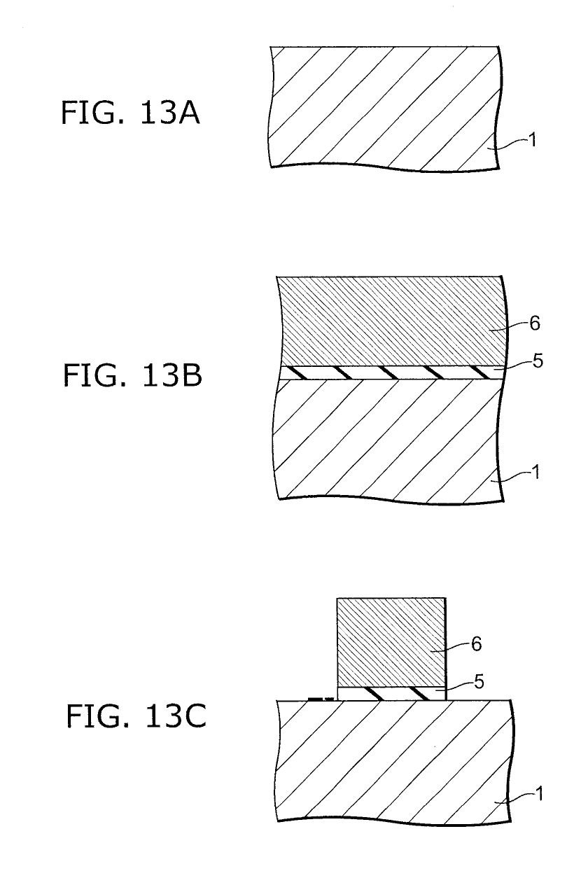

FIGS. 13A to 13C are schematic cross-sectional views in a process order illustrating the method for manufacturing the random number generation device according to the twelfth embodiment of the invention.

FIG. 13A is the view of the initial process, FIG. 13B is a view subsequent to FIG. 13A, and FIG. 13C is a view subsequent to FIG. 13B.

First, as shown in FIG. 13A, an impurity, for example, phosphor (P) is implanted into the silicon germanium (Si₁₋ₓGeₓ: 0<x≦1) substrate serving as the substrate 1 and annealed, thereby the silicon germanium (Si₁₋ₓGeₓ: 0<x≦1) layer having the impurity electrically activated is formed.

In the above, the silicon (Si) substrate is used instead of the silicon germanium (Si₁₋ₓGeₓ: 0<x≦1) substrate, the silicon germanium (Si₁₋ₓGeₓ: 0<x≦1) layer having the surface silicon (Si) atom and germanium (Ge) atom located at the equilibrium position is formed thereon with an enough thickness, and the impurity implantation and annealing for it can also form the silicon germanium (Si₁₋ₓGeₓ: 0<x≦1) layer having the impurity electrically activated.

Next, as shown in FIG. 13B, the hafnium silicon oxynitride (HfSiON) film serving as the first insulating film 5 having the trap and the polysilicon film serving as the gate electrode 6 are deposited, for example.

Thereafter, as shown in FIG. 13C, the above hafnium silicon oxynitride (HfSiON) film and the polysilicon film are processed into a desired shape by lithography and etching, and the first insulating film 5 and the gate electrode 6 are achieved.

After that, boron (B) is implanted, for example and annealing is performed, thereby the source region 2 and the drain region 3 are formed.

Thereafter, the insulating layer 7 such as SiN applying the expansion stress is deposited, for example, but a figure is omitted.

Thus, the random number generation device 112 according to this embodiment can be manufactured.

The random number generation device 112 manufactured like this can apply the expansion stress to the channel region 4 and the first insulating film 5. That is, synergistic use of the expansion stresses generating by the method using the lattice constant difference of the first embodiment, the method using the high relative dielectric constant material for the first insulating film 5 of the fourth embodiment and the method using the stress liner of the sixth embodiment is exemplified. Thus, the random number generation device decreasing the time constant of the RTS of the MISFET and generating the random number at a high speed can be provided.

The method based on the hole carrier according to the eleventh embodiment is also performed simultaneously, hence the random number generation device decreasing the time constant of the RTS of the MISFET and generating the random number at a high speed can be provided.

Moreover, also in the random number generation device 112 according to this embodiment, the random number generation device described in the second embodiment and outputting the random number by combining the random number generation device and the previously described pass gate 50 can be configured.

Moreover, providing the plurality of the random number generation devices and combining it with the logic circuit enable the random number generation device having a further high frequency of the random number generation and described in the third embodiment to be configured.

Thus, the random number generating device decreasing the time constant of the RTS of the MISFET, expanding the gate voltage range generating the RTS and generating the random number at a further high speed can be provided.

The embodiment of the invention has been described with reference to the examples. However, the invention is not limited to these examples.

For example, the specific configurations of respective elements constituting the random number generation device that is suitably selected from the publicly known ones by those skilled in the art is encompassed within the scope of the invention as long as the configurations can implement the invention similarly and achieve the same effects.

Components in two or more of the specific examples can be combined with each other as long as technically feasible, and such components are also encompassed within the scope of the invention as long as they fall within the spirit of the invention.

The random number generation device described above as the embodiment of the invention can be suitably modified and practiced by those skilled in the art, and such modifications are also encompassed within the scope of the invention as long as they fall within the spirit of the invention.

Various other variations and modifications can be conceived by those skilled in the art within the spirit of the invention, and it is understood that such variations and modifications are also encompassed within the scope of the invention.

1-20. (canceled)

21: A random number generation device comprising:
a first transistor including:
a first source region and a first drain region provided in a semiconductor layer;
a first channel region provided between the first source region and the first drain region;
a first insulating film provided on the first channel region and including a trap capturing and releasing a charge; and
a first gate electrode provided on the first insulating film;
a second transistor including:
a second source region and a second drain region provided in the semiconductor layer;
a second channel region provided between the second source region and the second drain region and made of a p-type semiconductor;
a second insulating film provided on the second channel region; and
a second gate electrode provided on the second insulating film, a first clock signal being inputted to the second gate electrode,
one of the second source region and the second drain region being connected to one of the first source region and the first drain region; and
a third transistor including:
a third source region and a third drain region provided in the semiconductor layer;
a third channel region provided between the third source region and the third drain region and made of an n-type semiconductor;
a third insulating film provided on the third channel region, and
a third gate electrode provided on the third insulating film, a second clock signal being inputted to the third gate electrode, a high/low relationship in a voltage of the second clock signal being inverted with respect to the first clock signal,
one of the third source region and the third drain region being connected to other of the first source region and the first drain region,
a tensile stress being applied in a gate length direction of the first transistor to at least one of the first channel region and the first insulating film, a tensile stress being applied in a gate length direction of the second transistor to at least one of the second channel region and the second insulating film, and a tensile stress being applied in a gate length direction of the third transistor to at least one of the third channel region and the third insulating film, or
a compressive stress being applied in a gate length direction of the first transistor to at least one of the first channel region and the first insulating film, a compressive stress being applied in a gate length direction of the second transistor to at least one of the second channel region and the second insulating film, and a compressive stress being applied in a gate length direction of the third transistor to at least one of the third channel region and the third insulating film.

22: The device according to claim 21, further comprising:
an insulating layer provided on a side face of the first gate electrode and a side face of the first insulating film and generating a tensile stress;
an insulating layer provided on a side face of the second gate electrode and a side face of the second insulating film and generating a tensile stress; and
an insulating layer provided on a side face of the third gate electrode and a side face of the third insulating film and generating a tensile stress, or
an insulating layer provided on a side face of the first gate electrode and a side face of the first insulating film and generating a compressive stress;
an insulating layer provided on a side face of the second gate electrode and a side face of the second insulating film and generating a compressive stress; and
an insulating layer provided on a side face of the third gate electrode and a side face of the third insulating film and generating a compressive stress.

23: The device according to claim 21, wherein the first channel region includes a first material of Si₁₋ₓGeₓ (0<x≦1).

24: The device according to claim 23, wherein the first source region and the first drain region includes a second material of Si_{1-y}Ge_{y} (0<y≦1) having a concentration of germanium different from a concentration of germanium in the first material.

25: The device according to claim 23, wherein the first source region and the first drain region includes silicon carbon (Si_{1-z}C_{z}: 0<z<1).

26: The device according to claim 21, wherein the first channel region includes a silicon layer provided on a material of Si₁₋ₓGeₓ(0<x≦1).

27: The device according to claim 26, wherein the first source region and the first drain region includes silicon carbon (Si_{1-z}C_{z}: 0<z<1).

28: The device according to claim 21, wherein a main component of a current passing through the first channel region is a hole.

29: The device according to claim 21, wherein at least a part of the first insulating film includes an insulating film provided adjacent to the first channel region and having a relative dielectric constant higher than 3.9.

30: The device according to claim 21, comprising a plurality of the random number generating devices, and further comprising a logic circuit,
a plurality of voltage signals being outputted from the random number generating devices, the voltage signals varying with time and the voltage signals being inputted to the logic circuit, and
the logic circuit generating a signal having a larger number of voltage variations in a unit time than the voltage signals.
